(19) United States
(12) Patent Application Publication
(10) Pub. No.: US 2025/0338489 A1
(43) Pub. Date: Oct. 30, 2025

(54) Semiconductor DEVICE AND METHOD OF FABRICATING THE SAME

(71) Applicant: Fujian Jinhua Integrated Circuit Co., Ltd., Quanzhou City (CN)

(72) Inventor: Yukihiro Nagai, Quanzhou City (CN)

(73) Assignee: Fujian Jinhua Integrated Circuit Co., Ltd., Quanzhou City (CN)

(21) Appl. No.: 18/892,570

(22) Filed: Sep. 23, 2024

(30) Foreign Application Priority Data
Apr. 24, 2024 (CN) 202410502333.8

(51) Int. Cl. H10B 12/00

(52) U.S. Cl. CPC H10B 12/50; H10B 12/01

(57) ABSTRACT

The present disclosure provides a semiconductor device and a method of fabricating the same including a first wire, a first insulating layer, a second wire, and a metal interconnecting structure. The first wire is disposed within a first dielectric layer. The first insulating layer is disposed on the first dielectric layer, covering the first wire. The second wire is disposed within a second dielectric layer, partially overlapping the first wire. The metal interconnecting structure is disposed within the second dielectric layer and the first insulating layer, to physically contact a top surface and a sidewall of the second wire and a top surface of the first wire. Through the arrangements of the metal interconnecting structure, the function and the structural reliability of interconnections will be improved, and the semiconductor device enables to gain an optimized operation and performance.

### BACKGROUND OF THE INVENTION

### 1. Field of the Invention

The present invention relates to a semiconductor device and a method of fabricating the same, and more particularly to a semiconductor device having a metal interconnecting structure and a method of fabricating the same.

### 2. Description of the Prior Art

Along with the continuously shrinking of this dimension, the design of a semiconductor device also faces highly integrated and high-speed operation challenges and limitations. In order to meet the requirements of highly integrated and high-speed operation, current techniques utilize miniaturized through holes and inter-layer dielectric layers to form a multilayered interconnection. Generally, the method of forming such interconnected wiring structure includes forming a through hole in a dielectric layer, and then sequentially forming various films in the through hole, such as a barrier layer and a conductive layer. However, as the increasing miniaturized cell-density of the semiconductor device, the current techniques can no longer define the position of the through hole, as well as controlling the CD thereof. If a dimensional shift or a dislocated through hole occurs, this can easily lead to serious defects to other components, thereby affecting the entire performance of the semiconductor device. For these reasons, the current approach for forming semiconductor device also encounters numerous problems. Therefore, how to improve the current issues while increasing the performance of the device still has become an important task in this field.

### SUMMARY OF THE INVENTION

It is one of the primary objectives of the present invention to provide a semiconductor device and a method of fabricating the same, where a metal interconnecting structure is arranged to electrically connect to both of a second wire disposed over an insulating layer and a first wire disposed below the insulating layer. Accordingly, the semiconductor device of the present disclosure enables to improve the function and the structural reliability of the interconnections under the space-saving requirement, so as to gain an optimized operation and performance.

To achieve the purpose described above, one embodiment of the present disclosure provides a semiconductor device including a first wire, a first insulating layer, a second wire, and a metal interconnecting structure. The first wire is disposed within a first dielectric layer. The first insulating layer is disposed on the first dielectric layer, covering the first wire. The second wire is disposed within a second dielectric layer, partially overlapping the first wire in a vertical direction. The metal interconnecting structure is disposed within the second dielectric layer and the first insulating layer, to physically contact a top surface and a sidewall of the second wire and a top surface of the first wire.

To achieve the purpose described above, one embodiment of the present disclosure provides a method of fabricating a semiconductor device, including the following steps. A first wire is formed. A first dielectric layer is formed at two sides of the first wire. A first insulating layer is formed on the first dielectric layer, covering the first wire. A second wire is formed, partially overlapping the first wire in a vertical direction. A second dielectric layer is formed at two sides of the second wire. A metal interconnecting structure is formed within the second dielectric layer and the first insulating layer, physically contacting a top surface and a sidewall of the second wire and a top surface of the first wire.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic cross-sectional diagram illustrating a semiconductor device according to a first embodiment of the present disclosure.

FIG. 2 to FIG. 6 are schematic diagrams illustrating a method of fabricating a semiconductor device according to a preferably embodiment of the present disclosure, wherein:

FIG. 2 is a schematic cross-sectional view of a semiconductor device after forming a first metal material layer;

FIG. 3 is a schematic cross-sectional view of a semiconductor device after forming a first wire;

FIG. 4 is a schematic cross-sectional view of a semiconductor device after forming a second metal material layer;

FIG. 5 is a schematic cross-sectional view of a semiconductor device after forming a second wire; and

FIG. 6 is a schematic cross-sectional view of a semiconductor device after forming a through hole.

FIG. 7 is a schematic cross-sectional diagram illustrating a semiconductor device according to a second embodiment of the present disclosure.

FIG. 8 is a schematic cross-sectional diagram illustrating a semiconductor device according to a third embodiment of the present disclosure.

FIG. 9 is a schematic cross-sectional diagram illustrating a semiconductor device according to a fourth embodiment of the present disclosure.

FIG. 10 is a schematic cross-sectional diagram illustrating a semiconductor device according to a fifth embodiment of the present disclosure.

### DETAILED DESCRIPTION

To provide a better understanding of the presented invention, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

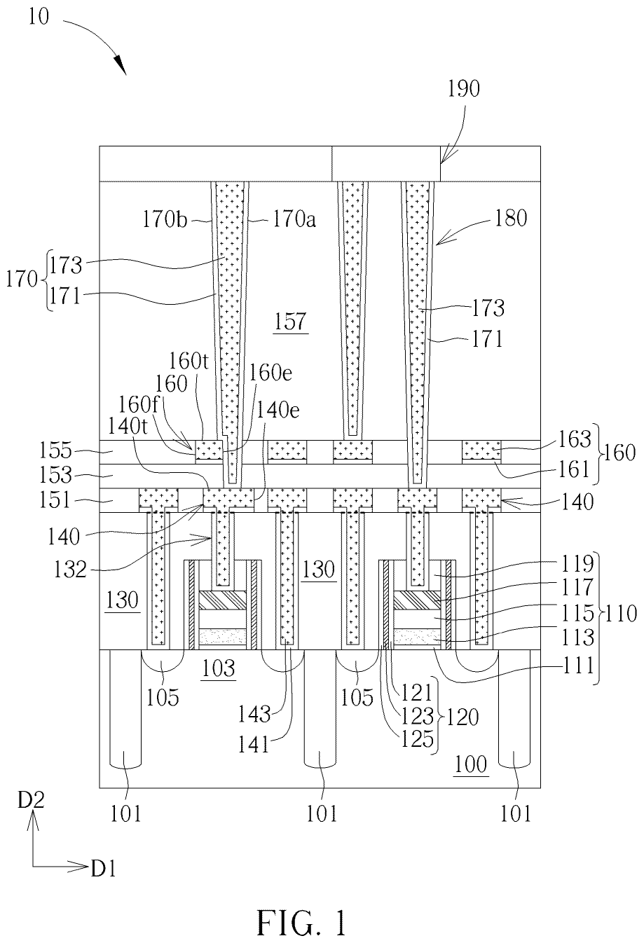

Please refer to FIG. 1, FIG. 1 is a schematic diagram illustrating a semiconductor device 10 according to the first embodiment of the present disclosure. As shown in FIG. 1, the semiconductor device 10 includes a first wire 140, a first insulating layer 153, a second wire 160 and a metal interconnecting structure 170. The first wire 140 is disposed within a first dielectric layer 151. The first insulating layer 153 is disposed on the first dielectric layer 151, covering the first wire 140. The second wire 160 is disposed within a second dielectric layer 155, partially overlapping the first wire 140 in a vertical direction D2. In one embodiment, the second wire 160 precisely includes a barrier layer 161 and a metal layer 163 stacked in sequence, with the barrier layer 161 for example including a conductive barrier material like titanium and/or titanium nitride, tantalum and/or tantalum nitride, and with the metal layer 163 for example including a low-resistance metal material like copper, aluminum, tungsten or other suitable material, but not limited thereto. The first dielectric layer 151, the first insulating layer 153 and the second dielectric layer 155 for example all include an insulating material like silicon oxide, silicon nitride, silicon oxynitride or silicon carbonitride, with the material of the first insulating layer 153 being preferably different from that of the first dielectric layer 151 and the second dielectric layer 155, but not limited thereto.

It is noted that the metal interconnecting structure 170 is disposed both within the second dielectric layer 155 and the first insulating layer 153, to physically contact a top surface 160t and a sidewall 160e of the second wire 160, and a top surface 140t of the first wire 140. That is, through arranging the metal interconnecting structure 170 at a position where is at least partially overlapped with the second wire 160 and the first wire 140, the metal interconnecting structure 170 is allowable to electrically connect the second wire 160 disposed above the first insulating layer 153, and the first wire 140 disposed below the first insulating layer 153 at the same time. With these arrangements, the metal interconnecting structure 170 of the present embodiment enables to electrically connect two separately arranged metal interconnections (namely, the first wire 140 and the second wire 160) at the same time, under a space-saving requirement. Then, the semiconductor device 10 of the present embodiment will therefore obtain components with improved function and reliability, so as to gain an optimized operation and performance thereby.

Precisely speaking, the metal interconnecting structure 170 is disposed within the first insulating layer 153, the second dielectric layer 155, and an inter-metal dielectric layer 157 over the second wire 160 at the same time, to obtain a relative greater extending length in the vertical direction D2. The metal interconnecting structure 170 includes a first sidewall 170a and a second sidewall 170b in the vertical direction D2. In one embodiment, the portion where the first sidewall 170a physically contacts the first wire 140 is preferably located at the top surface 140t of the first wire 140, in the vertical direction D2. That is, the falling location of the first sidewall 170a on the top surface 140t of the first wire 140 is not exceed to a sidewall 140e of the first wire 140 in a horizontal direction D1, as shown in FIG. 1. The rest portion of the first sidewall 170a where is not in direct contact with the first wire 140 may optionally extend outwardly, even extending beyond the sidewall 140e of the first wire 140 in the horizontal direction D1. Accordingly, the metal interconnecting structure 170 will therefore obtain a cross-section with a larger top and a smaller bottom, as shown in FIG. 1, being beneficial on improving the component reliability and simplifying the fabrication of the metal interconnecting structure 170. Also, the portion where the second sidewalls 170b physically contacts the second wire 160 is preferably located at the top surface 160t of the second wire 160, in the vertical direction D2. That is, the falling location of the second sidewall 170b on the top surface 160t of the second wire 160 is not exceed to a sidewall 160f of the second wire 160 in the horizontal direction D1, and the rest portion of the second sidewall 170b where is not in direct contact with the second wire 160 may optionally extend outwardly, even extending beyond the sidewall 160f of the second wire 160.

The semiconductor device 10 further includes a substrate 100, and the first wire 140, the first dielectric layer 151, the first insulating layer 153, the second wire 160, the second dielectric layer 155, and the metal interconnecting structure 170 are all disposed on the substrate 100. In one embodiment, the substrate 100 for example includes a silicon substrate, a silicon-containing substrate, an epitaxial silicon substrate, a silicon-on-insulator substrate, or a substrate being made of other suitable materials, but not limited thereto. The substrate 100 further includes a plurality of shallow trench isolations (STIs) 101 disposed therein, to define a plurality of active areas 103 within the substrate 100. Further in view of FIG. 1, the semiconductor device 10 further includes a plurality of gate structures 110 and a plurality of plugs 132. The gate structures 110 are separately disposed on the substrate 100, below the first wire 140. Each of the gate structures 110 precisely includes a gate dielectric layer 111, a semiconductor layer 113, a barrier layer 115, a metal layer 117 and a capping layer 119 stacked in sequence, with the gate dielectric layer 111 for example including an insulating material like silicon oxide, with the semiconductor layer 113 for example including a semiconductor material like doped polysilicon or doped amorphous silicon, with the barrier layer 115 for example including a conductive barrier material like titanium and/or titanium nitride, tantalum and/or tantalum nitride, with the metal layer 117 for example including a low-resistance metal material like copper, aluminum, tungsten or other suitable material, and with the capping layer 117 for example including an insulating material like silicon oxide, silicon nitride or silicon oxynitride, but not limited thereto.

Furthermore, a spacer structure 120 is disposed on two opposite sidewalls of each gate structure 110, and which includes a spacer layer 121, a spacer layer 123, and a spacer layer 125 stacked in sequence on the sidewalls. In one embodiment, the spacer layer 121 and the spacer layer 125 for example include the same insulating material like silicon nitride or silicon carbonitride, and the spacer layer 123 for example includes an insulating material being different from that of the spacer layers 121, 125, such as silicon oxide or silicon oxynitride, but not limited thereto. Then, each gate structure 110, and two doped regions 105 disposed at two sides of each gate structure 110, within the substrate 100 will together form a transistor component (not shown in the drawings). On the other hand, the plugs 132 are disposed within an interlayer dielectric layer 130 over the substrate 100 and the gate structures 110, with each plug 132 physically contacting the metal layer 117 of one gate structure 110, or one doped region 105 at one side of the gate structures 110. In one embodiment, the semiconductor device 10 for example includes a plurality of the first wires 140 and a plurality of the second wires 160, with each of the first wires 140 separately disposed within the first dielectric layer 151 to physically contact each plug 132 individually, and with each of the second wires 160 also being separately disposed within the second dielectric layer 155. Preferably, each first wire 140 and each plug 132 may be monolithic, with the monolithic structure including a barrier layer 141 and a metal layer 143 stacked in sequence as shown in FIG. 1, but not limited thereto. The barrier layer 141 for example includes a conductive barrier material like titanium and/or titanium nitride, tantalum and/or tantalum nitride, and with the metal layer 143 for example including a low-resistance metal material like copper, aluminum, tungsten or other suitable material, but not limited thereto. It is noted that, the first wire 140 and the second wire 160 of the present embodiment may be in direct connection with each other only through the metal interconnecting structure 170. Alternately, the first wire 140 and the second wire 160 may be in indirect connection, by respectively connecting to two plugs 180 disposed within the inter-metal dielectric layer 157, followed by both connecting to a connection structure 190 at the same time. In one embodiment, the metal interconnecting structure 170 and the plugs 180 each includes a barrier layer 171 and a metal layer 173 stacked in sequence, with the barrier layer 171 for example includes a conductive barrier material like titanium and/or titanium nitride, tantalum and/or tantalum nitride, and with the metal layer 173 for example including a low-resistance metal material like copper, aluminum, tungsten or other suitable material, but not limited thereto.

According to the semiconductor device 10 of the present embodiment, the metal interconnecting structure 170 is disposed at the position where is at least partially overlapped with the second wire 160 and the first wire 140, such that, the metal interconnecting structure 170 is allowable to be electrically connected to the second wire 160 disposed above the first insulating layer 153, and the first wire 140 disposed below the first insulating layer 153 at the same time, thereby improving the process window, as well as the structural reliability, of the metal interconnection at the same time. In this way, the first wire 140 and the second wire 160 will be in electrically connection directly through the metal interconnecting structure 170, thereby improving the function and the reliability of the components under a space-saving requirement. Then, the semiconductor device 10 of the present embodiment will therefore gain an optimized operation and performance.

In order to make those having ordinary skills in the art easily understand the semiconductor device 10 according to the present disclosure, a fabricating method of the semiconductor device 10 according to the present disclosure will be further described as follows.

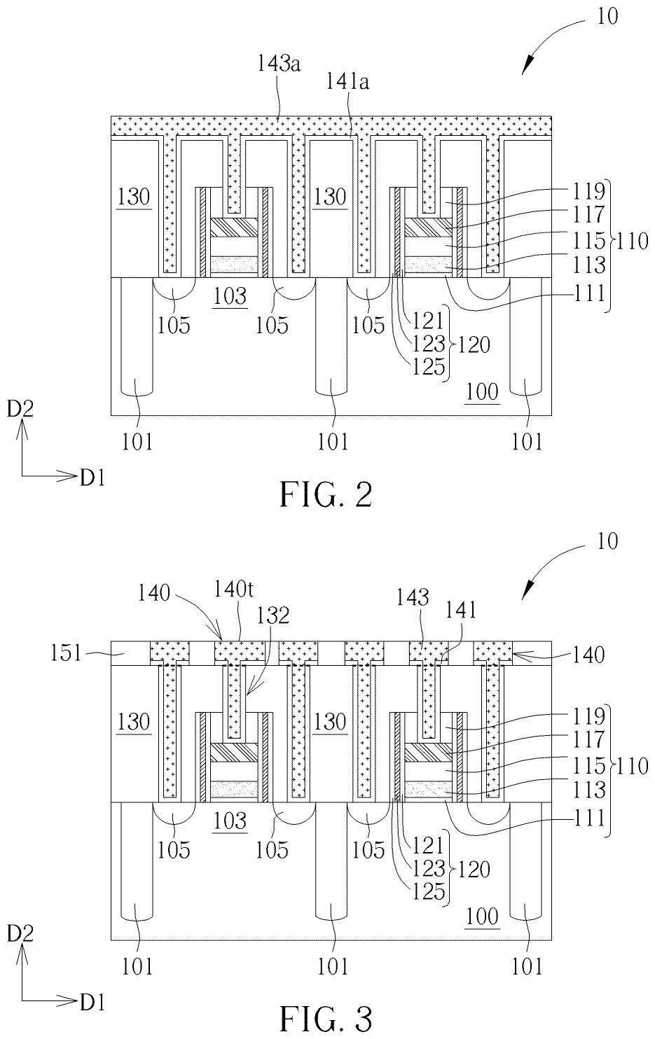

Please refer to FIG. 2 to FIG. 6, which are schematic diagrams illustrating a method of fabricating the semiconductor device 10 according to a preferably embodiment of the present disclosure. Firstly, as shown in FIG. 2, the substrate 100 is provided, and the shallow trench isolations 101 are formed within the substrate 100 to define the active areas 103. In one embodiment, the formation of the shallow trench isolations 101 is carried out by firstly forming a plurality of shallow trenches (not shown in the drawings) in the substrate 100 via an etching process, and at least one insulating material (such as including silicon oxide or silicon nitride) is filled in the shallow trenches, to form the shallow trench isolations 101 having a top surface being coplanar with the top surface of the substrate 100. Next, the gate structures 110 are formed on the substrate 100, the spacer structure 120 is then formed on the sidewalls of each of the gate structures 110, and the doped regions 105 are formed at two side of each gate structure 110 and the spacer structure 120 respectively, within the substrate 100. The formation of the gate structures 110 includes but not limited to the following steps. Firstly, a semiconductor material layer (not shown in the drawings, for example including a semiconductor material like doped polysilicon or doped amorphous silicon), a barrier material layer (not shown in the drawings, for example including a conductive barrier material like titanium and/or titanium nitride, tantalum and/or tantalum nitride), a metal material layer (not shown in the drawings, for example including a low-resistant metal material like tungsten, aluminum or copper), and a capping material layer (not shown in the drawings, for example including an insulating material like silicon oxide, silicon nitride or silicon oxynitride) are formed in sequence on the substrate 100, and a patterning process is performed on the capping material layer, the metal material layer, the barrier material layer and the semiconductor material layer, to simultaneously form the gate structures 110. The formation of the spacer structure 120 for example includes sequentially forming a first spacer material layer (not shown in the drawings, for example including silicon nitride or silicon carbonitride), a second spacer material layer (not shown in the drawings, for example including silicon oxide or silicon oxynitride), and a third spacer material layer (not shown in the drawings, for example including silicon nitride or silicon carbonitride) on the substrate 100, entirely covering the gate structures 110, followed by performing an etching back process, to form the spacer layer 121, the spacer layer 123 and the spacer layer 125 stacked sequentially on the sidewall of each gate structure 110, thereby together forming the spacer structure 120.

After that, a deposition process is performed to form the interlayer dielectric layer 130 on the substrate 100, entirely covering the gate structures 110 and the substrate 100, and a plurality of openings (not shown in the drawings) is formed within the interlayer dielectric layer 130 through a mask layer (not shown in the drawings), to respectively expose the metal layer 117 of the gate structures 110 and the doped region 105 at one side of the gate structures 110. In one embodiment, the interlayer dielectric layer 130 for example includes an insulating material like silicon oxide or silicon nitride, but not limited thereto. After completely removing the mask layer, another deposition process is performed to form a barrier material layer 141a (for example including a conductive barrier material like titanium and/or titanium nitride, tantalum and/or tantalum nitride) partially within the openings and partially outside the openings, as shown in FIG. 2. Then, the other deposition process is performed, to form a first metal material layer 143a (for example including a low-resistant metal material like tungsten, aluminum or copper) on the substrate 100, to fill up the rest space of each opening, and to further cover on the top surface of the interlayer dielectric layer 130.

As shown in FIG. 3, a first photolithography process is performed on the first metal material layer 143a and the barrier material layer 141a shown in FIG. 2, to simultaneously form the first wires 140 extending in the horizontal direction D1 and the plugs 132 extending in the vertical direction D2. Accordingly, each first wire 140 and each plug 132 will be monolithic, with the monolithic structure including the barrier layer 141 and the metal layer 143 stacked in sequence. Then, a deposition process and an etching back process are performed, to form the first dielectric layer 151 being coplanar with the top surface 140t of the first wires 140, such that, the first wires 140 are namely formed within the first dielectric layer 151.

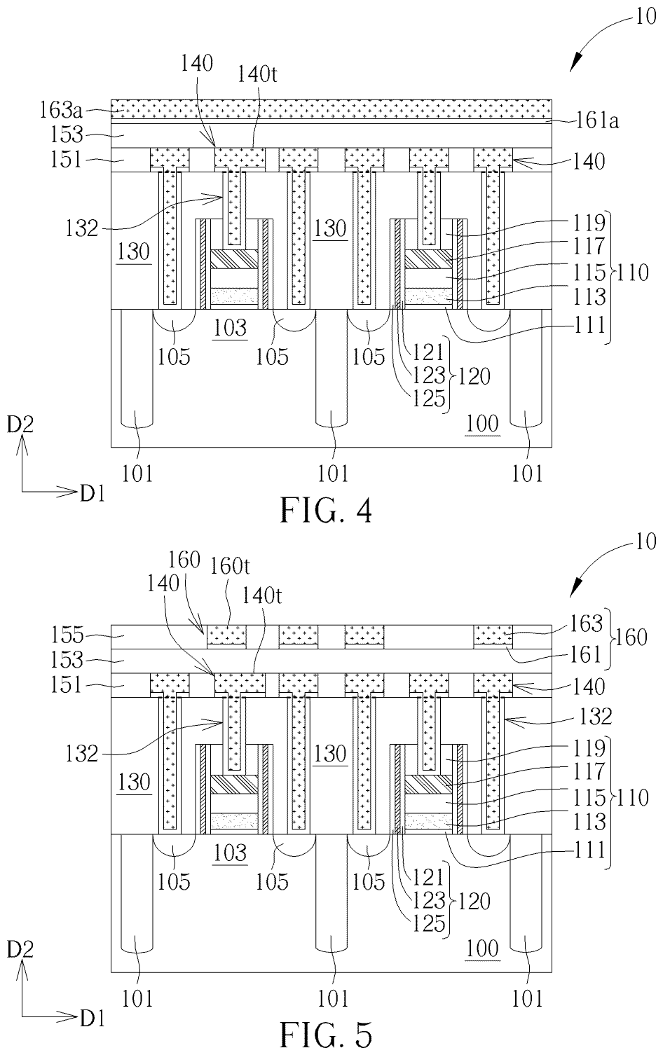

As shown in FIG. 4, a multi-deposition process is performed, to form the first insulating layer 153, a barrier material layer 161a, and a second material layer 163a in sequence, with each of the first insulating layer 153, the barrier material layer 161a and the second metal material layer 163a entirely covering on the first wire 140 and the first dielectric layer 151.

As shown in FIG. 5, a second photolithography process is performed on the second metal material layer 163a and the barrier material layer 161a, to form the second wires 160 extending in the horizontal direction D1. Then, a deposition process and an etching back process are performed, to form the second dielectric layer 155 being coplanar with the top surface 160t of the second wires 160, and the second wires 160 are therefore formed within the second dielectric layer 155.

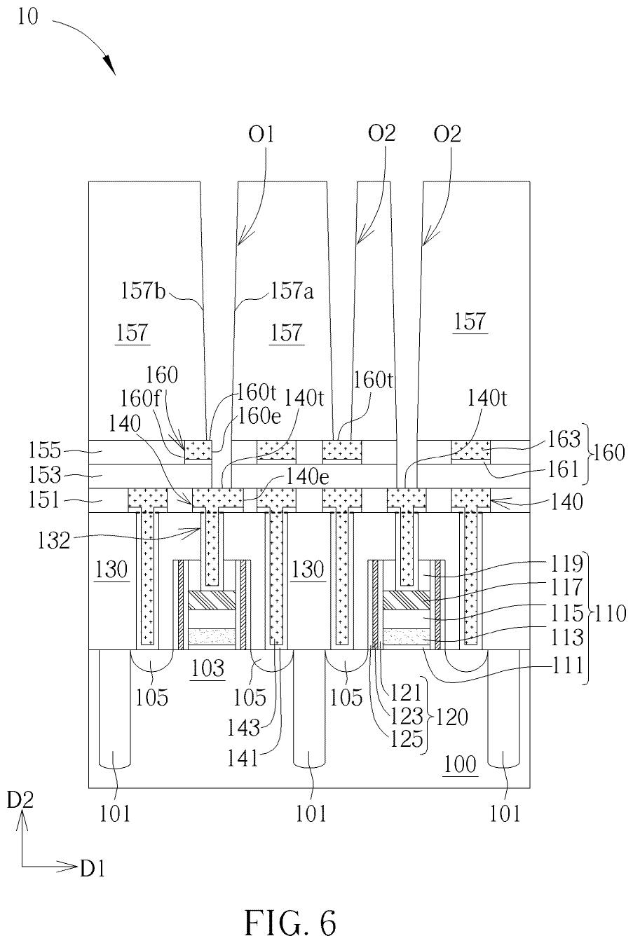

As shown in FIG. 6, a deposition process is further performed on the substrate 100, to form the inter-metal dielectric layer 157, covering the second wires 160 and the second dielectric layer 155. Then, a plurality of through holes O1, O2 is formed within the inter-metal dielectric layer 157 through a self-aligned etching process, by using a mask layer (not shown in the drawings) and at least one second wire 160 as a self-aligned mask. The through hole O1 penetrates through the inter-metal dielectric layer 157, the second dielectric layer 155 and the first insulating layer 153 in sequence, to expose the top surface 160t and the sidewall 160e of the second wire 160, as well as the top surface 140t of the first wire 140, at the same time. Each of the through holes O2 penetrates through the inter-metal dielectric layer 157, the second dielectric layer 155 and/or the first insulating layer 153 in sequence, to expose the top surface 160t of the second wire 160 or to expose the top surface 140t of the first wire 140. In another embodiment, the formation of the through holes O1, O2 may be optionally integrated with the fabrication of other interconnection structure, to obtain a relative greater length in the vertical direction D2, for example being about 10-20 times greater than the length of the first wire 140 or the second wire 160, but not limited thereto. It is noted that, the through holes O1, O2 may each include a cross-section with a larger top and a smaller bottom as shown in FIG. 6, due to the etching loading effect, but not limited thereto. The portion where a sidewall 157a of the through hole O1 physically contacts the first wire 140 in the vertical direction D2 is preferably located on the top surface 140t of the first wire 140, without exceeding the sidewall 140e of the first wire 140 in the horizontal direction D1. Likewise, the portion where the sidewall 157b of the through hole 01 physically contacts the second wire 160 in the vertical direction D2 is also preferably located on the top surface 160t of the second wire 160, without exceeding the sidewall 160f of the second wire 160 in the horizontal direction D1. With these performances, it is beneficial on simplifying the fabrication of the through holes O1, O2, avoiding the possible defects occurred on the through holes O1, O2 due to the increasing miniaturized critical size, and effectively improving the component reliability of the metal interconnecting structure 170 formed subsequently.

Following these, after completely removing the mask layer, a deposition process is further performed, to sequentially form a barrier material layer (not shown in the drawings, for example including a conductive barrier material like titanium and/or titanium nitride, tantalum and/or tantalum nitride), and a metal material layer (not shown in the drawings, for example including a low-resistance metal material like copper, aluminum, tungsten or other suitable material) in the through holes O1, O2, with the barrier material layer physically contacting the top surface 140t of the first wire 140, and the top surface 160t and the sidewall 160e of the second wire 160. Subsequently, a planarization process is performed on the barrier material layer and the metal material layer, to form the metal interconnecting structure 170 and the plug 180 within the through holes O1, O2 respectively, as shown in FIG. 1. In this way, the first wire 140 and the second wire 160 may be electrically connected with each other in a direct manner through the metal interconnecting structure 170. Otherwise, the connection structure 190 respectively connected to two plugs 180 may be further formed over the inter-metal dielectric layer 157, such that, the first wire 140 and the second wire 160 may be electrically connected with each other in an indirect manner, through the connection structure 190.

According to the method of fabricating the semiconductor device of the present disclosure, the through hole O1 is formed over the second wire 160 and the second dielectric layer 155, by penetrating through the second dielectric layer 155 and the first insulating layer 153 at the same time, and the through hole 01 formed accordingly will include the cross-section with a larger top and the smaller bottom. Then, the metal interconnecting structure 170 is formed within the through hole O1, to electrically connect both of the second wire 160 disposed above the first insulating layer 153, and the first wire 140 disposed below the first insulating layer 153. Through these performances, the metal interconnecting structure 170 will correspondingly include a cross-section with a larger top and the smaller bottom, to physically contact the top surface 160t and the sidewall 160e of the second wire 160, and the top surface 140t of the first wire 140 at the same time. The positions where the first sidewall 170a physically contacts the top surface 140t of the first wire 140, and the second sidewall 170b physically contacts the top surface 160t of the second wire 160 are not beyond the sidewall 140e of the first wire 140, or not beyond the sidewall 160e of the second wire 160. In this way, the interconnection with improved function and reliable structure is allowable to be fabricated due to the fabricating method of the present embodiment, so that, the process window of the interconnection will be effectively saving under a simplified process flow, so as to form the semiconductor device 10 with the optimized operation and performance.

Those of ordinary skill in the art should easily realize the semiconductor device and the fabricating method thereof in the present disclosure are not limited to the aforementioned embodiment, and which may include other examples or varieties. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

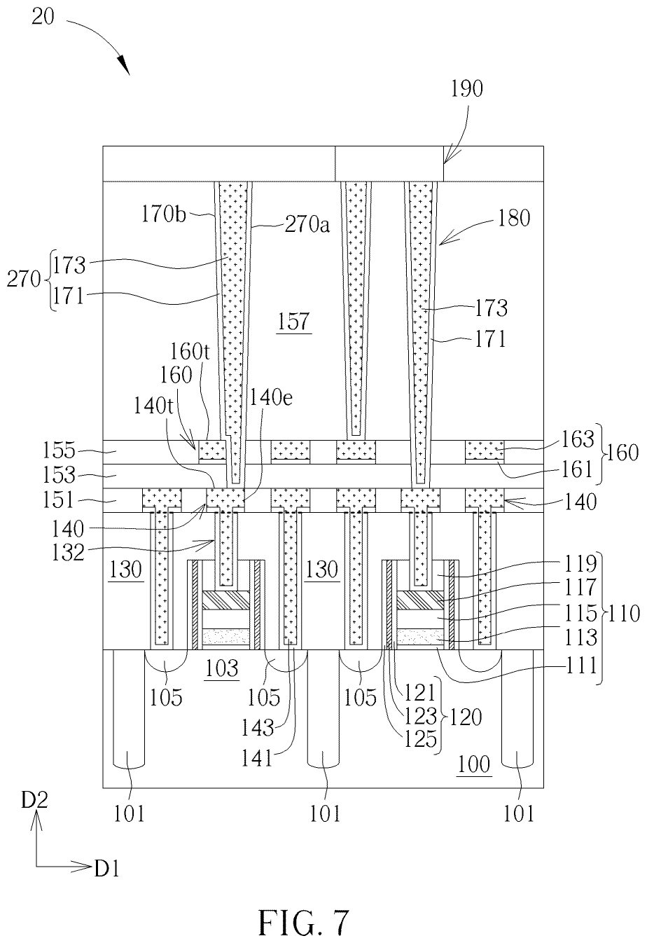

Please refer to FIG. 7, which is a schematic cross-sectional view of a semiconductor device 20 according to the second embodiment of the present disclosure. The structure of the semiconductor device 20 in the present embodiment is substantially the same as that of the semiconductor device 10, and all the similarities will not be redundantly described hereinafter. The difference between the semiconductor device 20 in the present embodiment and the semiconductor device 10 in the aforementioned embodiment is mainly in that the portion where a first sidewall 270a of a metal interconnecting structure 270 physically contacts the first wire 140 is located on the top surface 140t of the first wires 140, being vertically aligned with the sidewall 140e of the first wire 140 in the vertical direction D2. That is, the metal interconnecting structure 270 will also include a cross-section with a larger top and a smaller bottom, so as to gain better component reliability under a simplified fabrication.

According to the semiconductor device 20 of the present embodiment, the metal interconnecting structure 270 is also disposed at the position where is at least partially overlapped with the second wire 160 and the first wire 140, such that, the metal interconnecting structure 270 is still allowable to electrically connect both of the second wire 160 disposed above the first insulating layer 153, and the first wire 140 disposed below the first insulating layer 153, improving the process window, as well as the structural reliability, of metal interconnection at the same time. In this way, the semiconductor device 20 of the present embodiment also enables to obtain the improved function and the reliability of the components under a space-saving requirement, so as to achieve an optimized operation and performance.

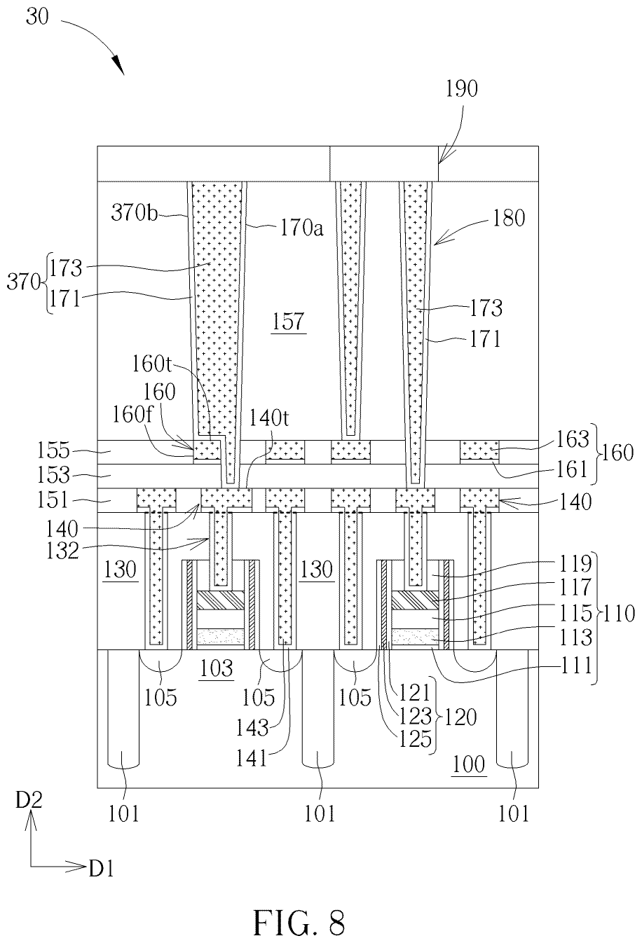

Please refer to FIG. 8, which is a schematic cross-sectional view of a semiconductor device 30 according to the third embodiment of the present disclosure. The structure of the semiconductor device 30 in the present embodiment is substantially the same as that of the semiconductor device 10, and all the similarities will not be redundantly described hereinafter. The difference between the semiconductor device 30 in the present embodiment and the semiconductor device 10 in the aforementioned embodiment is mainly in that a portion where a second sidewall 370b of a metal interconnecting structure 370 physically contacts the second wire 160 is located on the top surface 160t of the second wires 160, being vertically aligned with the sidewall 160f of the second wire 160 in the vertical direction D2. That is, the metal interconnecting structure 370 will also include a cross-section with a larger top and a smaller bottom, so as to gain better component reliability under a simplified fabrication.

According to the semiconductor device 30 of the present embodiment, the metal interconnecting structure 370 is also disposed at the position where is at least partially overlapped with the second wire 160 and the first wire 140, such that, the metal interconnecting structure 270 is still allowable to electrically connect both of the second wire 160 disposed above the first insulating layer 153, and the first wire 140 disposed below the first insulating layer 153, improving the process window, as well as the structural reliability, of metal interconnection at the same time. In this way, the semiconductor device 30 of the present embodiment also enables to obtain the improved function and the reliability of the components under a space-saving requirement, so as to achieve an optimized operation and performance.

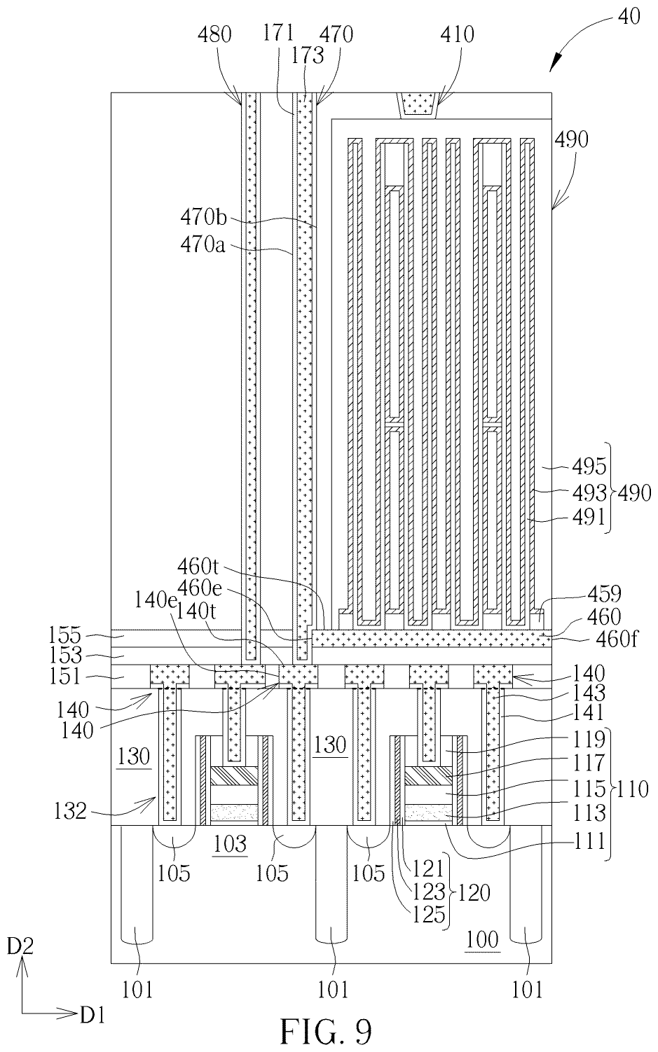

Please refer to FIG. 9, which is a schematic cross-sectional view of a semiconductor device 40 according to the fourth embodiment of the present disclosure. The structure of the semiconductor device 40 in the present embodiment is substantially the same as that of the semiconductor device 10, and all the similarities will not be redundantly described hereinafter. The difference between the semiconductor device 40 in the present embodiment and the semiconductor device 10 in the aforementioned embodiment is mainly in that the semiconductor device 40 further includes a capacitor structure 490 disposed on a second wire 460, to physically contact the second wire 460.

Precisely speaking, the second wire 460 of the present embodiment may be disposed within the second dielectric layer 155, over the first insulating layer 153, and which may include a low-resistance metal material like copper, aluminum, tungsten or other suitable material, but not limited thereto. A second insulating layer 459 is further disposed on the second wire 460, at least partially covering the top surface 460t of the second wire 460, and the capacitor structure 490 is disposed on the second insulating layer 459 with a portion thereof being penetrated through the second insulating layer 459 to electrically connect the second wire 460. The capacitor structure 490 precisely includes a plurality of bottom electrode layers 491, a capacitor dielectric layer 493, and a top electrode layer 495 stacked in sequence, with each of the bottom electrode layers 491 penetrating through the second insulating layer 459 and having a U-shaped cross-section, to physically contact and to electrically connect the second wire 460 below the second insulating layer 459.

It is noted that, the semiconductor device 40 further includes a metal interconnecting structure 470 disposed at the position where is at least partially overlapped with the second wire 160 and one first wire 140 physically contacting the doped region 105, such that, the metal interconnecting structure 470 is also allowable to electrically connect both of the second wire 160 and the first wire 140 under the space-saving requirement. Also, the metal interconnecting structure 470 includes a first sidewall 470a and a second sidewall 470b in the vertical direction D2, and the portion where the first sidewall 470a physically contacts the top surface 140t of first wire 140, or the second sidewall 470b physically contacts the top surface 460t of second wire 460, is not beyond the sidewall 140e of the first wire 140 or the sidewall 460f of the second wire 460, as shown in FIG. 9. In one embodiment, the portion where the first sidewall 470a physically contacts the top surface 140t of first wire 140, or the second sidewall 470b physically contacts the top surface 460t of second wire 460 may be vertically aligned with the sidewall 140e of the first wire 140 or the sidewall 460f of the second wire 460 optionally, but not limited thereto. That is, the metal interconnecting structure 470 will also include a cross-section with a larger top and a smaller bottom, so as to gain better component reliability under a simplified fabrication.

In another embodiment, formation of the metal interconnecting structure 470 may be optionally carried out after forming the capacitor structure 490, being integrated with the fabrication of other interconnection structure, like a plug 480 being electrically connected to one corresponding first wire 140, to obtain a greater length in the vertical direction D2, for example being about ten times to twenty times of the length of the first wire 140 or second wire 460, but not limited thereto. Following these, a connection structure 410 may be additional disposed on the capacitor structure 490, and then the capacitor structure 490 may be further electrically connected to different components through the connecting structure 410, thereby forming various device for achieving different operations.

According to the semiconductor device 40 of the present embodiment, the metal interconnecting structure 470 is allowable to electrically connect both of the second wire 460 disposed above the first insulating layer 153, and the first wire 140 disposed below the first insulating layer 153, improving the process window, as well as the structural reliability of metal interconnection at the same time. Furthermore, through the semiconductor device 40 of the present embodiment, the capacitor structure 490 disposed over the second wire 460 may be further electrically connected to the doped region 105 of the transistor component through the metal interconnecting structure 470, and then, the capacitor structure 490 and the transistor component will together form the smallest memory cell of a memory device for receiving voltage signals from bit lines (not shown in the drawings) and word lines (not shown in the drawings). The smallest memory cell may be further electrically connected to any required component through the connection structure 410 disposed on the capacitor structure 490, such that, the semiconductor device 40 will therefore serve as a dynamic random access memory (DRAM) device for achieving an optimized operation and performance.

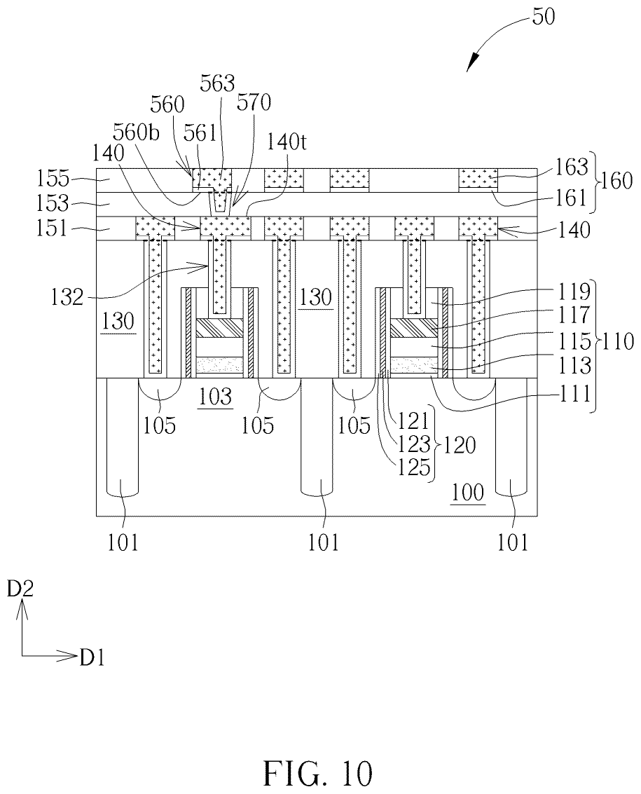

Please refer to FIG. 10, which is a schematic cross-sectional view of a semiconductor device 50 according to the fifth embodiment of the present disclosure. The structure of the semiconductor device 50 in the present embodiment is substantially the same as that of the semiconductor device 10, and all the similarities will not be redundantly described hereinafter. The difference between the semiconductor device 50 in the present t embodiment and the semiconductor device 10 in the aforementioned embodiment is mainly in that a metal interconnecting structure 570 is disposed between the top surface 140t of the first wire 140 and the bottom surface 560b of the second wire 560.

Precisely speaking, the metal interconnecting structure 570 is disposed within the first insulating layer 153, below the second wire 560. Preferably, the metal interconnecting structure 570 and the second wire 560 are monolithic, with the monolithic structure including a barrier layer 561 and a metal layer 563 stacked in sequence as shown in FIG. 10, but not limited thereto. the barrier layer 561 for example includes a conductive barrier material like titanium and/or titanium nitride, tantalum and/or tantalum nitride, and the metal layer 563 for example includes a low-resistance metal material like copper, aluminum, tungsten or other suitable material, but not limited thereto. Accordingly, the first wire 140 and the second wire 560 may be in directly electrically connection with each other through the metal interconnecting structure 570.

According to the semiconductor device 50 of the present embodiment, the metal interconnecting structure 570 is also disposed at the position where is at least partially overlapped with the second wire 560 and the first wire 140, such that, the metal interconnecting structure 570 is still allowable to electrically connect both of the second wire 560 disposed above the first insulating layer 153, and the first wire 140 disposed below the first insulating layer 153, thereby improving the process window, as well as the structural reliability, of metal interconnection at the same time. In this way, the semiconductor device 50 of the present embodiment also enables to obtain the improved function and the reliability of components under a space-saving requirement, to achieve the optimized operation and performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a first wire, disposed within a first dielectric layer;
a first insulating layer, disposed on the first dielectric layer and covering the first wire;
a second wire, disposed within a second dielectric layer, partially overlapping the first wire in a vertical direction; and
a metal interconnecting structure, disposed within the second dielectric layer and the first insulating layer, to physically contact a top surface and a sidewall of the second wire, and a top surface of the first wire.

2. The semiconductor device according to claim 1, wherein a position where a first sidewall of the metal interconnecting structure physical contacts the top surface of the first wire does not exceed a sidewall of the first wire.

3. The semiconductor device according to claim 2, wherein the first sidewall of the metal interconnecting structure is vertically aligned with the sidewall of the first wire.

4. The semiconductor device according to claim 2, wherein a position where a second sidewall of the metal interconnecting structure physical contacts the top surface of the second wire does not exceed another sidewall of the second wire.

5. The semiconductor device according to claim 4, wherein the second sidewall of the metal interconnecting structure is vertically aligned with the another sidewall of the second wire.

6. The semiconductor device according to claim 1, wherein the metal interconnecting structure comprises a cross-section with a larger top and a smaller bottom.

7. The semiconductor device according to claim 1, further comprising:
a gate structure, disposed under the first wire; and
a plug, disposed on the gate structure and physically contacting the gate structure and the first wire.

8. The semiconductor device according to claim 1, further comprising:
a gate structure, disposed under the first wire; and
a plug, disposed under the first wire and physically contacting the first wire and a doped region at a side of the gate structure.

9. The semiconductor device according to claim 8, further comprising:
a capacitor structure, disposed on the second wire and physically contacting the second wire.

10. The semiconductor device according to claim 9, further comprising:
a second insulating layer disposed on the second wire, wherein the capacitor structure further comprising a plurality of bottom electrode layers, a capacitor dielectric layer and a top electrode layer, and each of the bottom electrode layers penetrates through the second insulating layer and physically contacts the top surface of the second wire.

11. A method of fabricating a semiconductor device, comprising:
forming a first wire;
forming a first dielectric layer, at two sides of the first wire;
forming a first insulating layer on the first dielectric layer, covering the first wire;
forming a second wire, partially overlapping the first wire in a vertical direction;
forming a second dielectric layer at two sides of the second wire; and
forming a metal interconnecting structure within the second dielectric layer and the first insulating layer, the metal interconnecting structure physically contacting a top surface and a sidewall of the second wire, and a top surface of the first wire.

12. The method of fabricating the semiconductor device according to claim 11, forming of the first wire and the second wire further comprising:
forming a first metal material layer;
performing a first photolithography process on the first metal material layer, to form the first wire;
after the first photolithography process, forming a second metal material layer on the first insulating layer; and
performing a second photolithography process on the second metal material layer, to form the second wire.

13. The method of fabricating the semiconductor device according to claim 12, wherein the first dielectric layer is formed after the first photolithography process, the second dielectric layer is formed after the second photolithography process, and the metal interconnecting structure is formed after the second dielectric layer is formed.

14. The method of fabricating the semiconductor device according to claim 13, forming the metal interconnecting structure further comprising:
forming a through hole penetrating through the second dielectric layer and the first insulating layer; and
sequentially forming a barrier material layer and a metal material layer within the through hole, to form the metal interconnecting structure, wherein the barrier material layer physically contacts the top surface and the sidewall of the second wire, and the top surface of the first wire.

15. The method of fabricating the semiconductor device according to claim 11, further comprising:
before forming the first wire, forming a gate structure; and
forming a plug on the gate structure, wherein the plug physically contacts the gate structure and the first wire.

16. The method of fabricating the semiconductor device according to claim 11, further comprising:
before forming the first wire, forming a gate structure; and
forming a plug under the first wire, wherein the plug physically contacts the first wire and a doped region at a side of the gate structure.

17. The method of fabricating the semiconductor device according to claim 16, further comprising:
forming a second insulating layer on the second wire; and
forming a capacitor structure on the second insulating layer, wherein the capacitor structure physically contacts the second wire.

18. The method of fabricating the semiconductor device according to claim 17, wherein the capacitor structure further comprises a plurality of bottom electrode layers, a capacitor dielectric layer, and a top electrode layer, and each of the bottom electrode layers penetrates through the second insulating layer and physically contacts the top surface of the second wire.

19. The method of fabricating the semiconductor device according to claim 18, wherein a position where a first sidewall of the metal interconnecting structure physical contacts the top surface of the first wire does not exceed a sidewall of the first wire.

20. The method of fabricating the semiconductor device according to claim 18, wherein a position where a second sidewall of the metal interconnecting structure physical contacts the top surface of the second wire does not exceed another sidewall of the second wire.
